(19) United States
(12) Patent Application Publication
(10) Pub. No.: US 2016/0276328 A1
(43) Pub. Date: Sep. 22, 2016

(54) LIGHT-EMITTING DEVICE, DEVICE AND METHOD FOR ADJUSTING THE LIGHT EMISSION OF A LIGHT-EMITTING DIODE

(71) Applicant: COMMISSARIAT À L'ÉNERGIE ATOMIQUE ET AUX ÉNERGIES ALTERNATIVES, Paris (FR)

(72) Inventors: Ivan-Christophe ROBIN, Grenoble (FR); Alexei TCHELNOKOV, Meylan (FR); Bruno MOUREY, Coublevie (FR)

(73) Assignee: Commissariat a l'energie atomique et aux energies alternatives, Paris (FR)

(21) Appl. No.: 15/031,992

(22) PCT Filed: Oct. 24, 2014
(86) PCT No.: PCT/EP14/72898

§ 371 Date: Apr. 25, 2016

(30) Foreign Application Priority Data
Oct. 25, 2013 (FR) 13 60416

(51) Int. Cl. H01L 25/16; H01L 33/32; H05B 33/08; H01L 33/08; H01L 33/00; H01L 33/50; H01L 33/06; H01L 31/147

(52) U.S. Cl. CPC H01L 25/167; H01L 33/06; H01L 33/32; H01L 31/147; H01L 33/08; H01L 33/0025; H01L 33/502; H05B 33/0848; H05B 33/0866

(57) ABSTRACT

Light-emitting device (100) comprising:
a light-emitting diode (102) comprising:
   an emitting layer comprising a ternary or quaternary semiconductor including a chemical element from column 13 of the periodic table of elements, among Al, Ga and In, of which the atomic composition varies over the thickness of the emitting layer, and/or
   at least two emitting layers each comprising such a semiconductor, the atomic compositions of said element being different from one layer to another,
a device (108) that detects a wavelength and an intensity of a light emitted by the diode,
a switched-mode electric power supply (110) able to power the diode with a periodic signal comprising a duty cycle α,
a device (111) for controlling the switched-mode electric power supply which can alter α and a peak value of the periodic signal according to the values detected and target values.

### TECHNICAL FIELD ET PRIOR ART

The invention relates to the field of light-emitting diodes (named LEDs), and in particular that of light-emitting devices comprising one or several LEDs (bulbs, screens, projectors, display walls, etc.). The invention also relates to a device and a method for adjusting the light emission characteristics of an LED, able to be used in particular to determine the electrical power supply parameters of the LED making it possible to obtain a light emission according to a desired wavelength and intensity.

During the making of some LEDs, such as LEDs intended to be coupled with phosphorus that converts a portion of the blue light emitted by LEDs into a yellow light and have in the end an emission of white light, these LEDs are sorted at the output of production in order to retain only those for which the emission wavelength corresponds precisely to the sought wavelength, for example the optimum wavelength to excite the phosphorus in the case of LEDs used to emit a white light. However, the value of the wavelength emitted by the LEDs depends on several parameters of LEDs, in particular the composition of the materials of the quantum wells of the LEDs and the thickness of these quantum wells.

For the production of these LEDs, a large-size substrate (100 mm, 150 mm, or 200 mm in diameter) is used to increase various semiconductor materials (for example via epitaxy), these stacks of materials forming in particular the quantum wells corresponding to the emitting layers of the LEDs. The substrate is then cut into very small rectangles (dies), forming individual chips comprising one or several LEDs. Electrical contacts are then made and phosphorus is added in the form of a coating on the emitting portion of the LEDs.

Slight variations in the thickness of the quantum wells and/or in the composition of the materials of the quantum wells, due to the steps of manufacturing implemented, have a significant influence on the emission wavelength obtained as output from the LEDs. As such, for an LED comprising several quantum wells including InGaN and emitting normally at a wavelength of about 420 nm, a modification of about 1% in the indium composition in the semiconductor of the quantum wells, i.e. the proportion of indium in the InGaN, modifies by about 5 nm the wavelength emitted by the LED. Likewise, a modification of about 0.5 nm in the thickness of one of the quantum wells of InGaN of a nominal thickness of about 2.5 nm of such an LED results in an offset in the emission wavelength of about 10 nm.

However, the values of these two parameters (thickness and composition of the materials of the quantum wells) can vary substantially from one LED to another at the output of production, in particular dues to the growth processes implemented for their manufacture, which can create substantial variations in the colour emitted in the end by the LEDs.

### DISCLOSURE OF THE INVENTION

A purpose of this invention is to propose a light-emitting device comprising at least one light-emitting diode and which makes it possible to be free from and offset any variations in the wavelength emitted by the light-emitting diode, for example due to structural variations of the light-emitting diode and in particular of the thickness and/or of the composition of the materials of the emitting layer or layers of the light-emitting diode.

For this, this invention proposes a light-emitting device comprising at least:
a light-emitting diode comprising:
   at least one emitting layer able to form a quantum well and comprising a ternary or quaternary semiconductor including at least one chemical element from column 13 of the periodic table of elements, among Al, Ga and In, and having an atomic composition, or atomic percentage, that varies over the thickness of the emitting layer, and/or
   at least two emitting layers able to form two quantum wells and each comprising a ternary or quaternary semiconductor including at least one chemical element from column 13 of the periodic table of elements, among Al, Ga and In, the atomic compositions, or atomic percentages, of said chemical element in the emitting layers being different from one to another,
a device for detecting the value of a wavelength and of an intensity of a light intended to be emitted by the light-emitting diode,
a switched-mode electric power supply able to electrically power the light-emitting diode with a periodic signal comprising a duty cycle α such that αε]0;1],
a device for controlling the switched-mode electric power supply, which can alter a peak value and the duty cycle α of the periodic signal respectively according to values of the wavelength and of the intensity of the light intended to be detected and according to the target values of the wavelength and of the intensity.

Such a light-emitting device therefore makes it possible to offset any variations in the wavelength emitted by the light-emitting diode, for example due to variations in the structure of the emitting layers of the light-emitting diode, by adjusting the electric power supply parameters of the light-emitting diode. Indeed, if the light-emitting diode emits, when it is supplied with a standard periodic signal, a light of which the value of the wavelength does not correspond to the target value sought (for example the optimal excitation wavelength of phosphorus), this difference between the value of the wavelength emitted and the target value is detected by the device for detecting of the light-emitting device. The device for controlling the light-emitting device then adapts the peak value of the periodic signal supplying the light-emitting diode, as such modifying the current density passing through the light-emitting diode, which makes it possible to offset the value of the wavelength emitted by the light-emitting diode to the target value sought.

The modification of the current density passing through the light-emitting diode results in a change in the intensity of the light emitted by the light-emitting diode. So that this modification in the value of the current density passing through the light-emitting diode does not affect the intensity with which the light is emitted by the light-emitting diode and that the value of the intensity of the light emitted corresponds to the target value sought of this light intensity, the device for controlling also adapts the duty cycle α of the periodic signal of the electrical supply of the light-emitting diode so that the light emission carried out by the light-emitting diode at the correct wavelength is also with a light intensity that corresponds to the target intensity value sought.

Furthermore, so that it is possible to adjust the emitting wavelength of the light-emitting diode in a range of values that is sufficiently wide, the light-emitting device also uses a light-emitting diode comprising one or several emitting layers forming one or several quantum wells that have variations in the atomic composition of a chemical element from column 13, or column IIIA, of the periodic table of elements of the ternary or quaternary semiconductor or semiconductors of this or of these emitting layers, with these variations corresponding either variations in the atomic composition of said chemical element within the emitting layer or of each one of the emitting layers, or to atomic compositions of said chemical element that are different from one layer to another. Such inhomogeneities in compositions, that vary the gap energy in the emitting layer or layers, favour the adaptability in wavelength of the light-emitting diode by making it possible to have greater latitude on the adjustment of the emission wavelength of the light-emitting diode with respect to a light-emitting diode that would include one or several emitting layers of which the atomic composition of said chemical element of the semiconductor of this or of these layers would be a constant value in the entire active zone that contains this or these emitting layers.

The ternary or quaternary semiconductor may comprise at least one chemical element from column 13, or column IIIA, of the periodic table of elements among Al, Ga and In, and may further comprise at least one chemical element from column 15, or column VA, of the periodic table of elements. The chemical element from column 15 of the periodic table of elements may be chosen among N, P, As and Sb. In the case of a ternary semiconductor, that latter may comprise a chemical element from column 15 of the periodic table of elements and two chemical elements from column 13 of the periodic table of elements, corresponding for example to InGaN. In the case of a quaternary semiconductor, that latter may comprise a chemical element from column 15 of the periodic table of elements and three chemical elements from column 13 of the periodic table of elements, corresponding for example to GaAlInN or GaAlInP or GaAlInAs.

The chemical elements of the semiconductors of the emitting layers may be of a similar nature in all of the emitting layers, only the atomic compositions of said chemical element varying within the emitting layers being different from one emitting layer to another.

Said chemical element may be indium or aluminium. For example, when the semiconductor is In_{X}Ga_{(1-X)}N, the expression “atomic composition of said chemical element” corresponds to the atomic percentage X of indium in this semiconductor. In this case, the gap of the quantum well varies according to the atomic percentage X of said chemical element in this semiconductor. In addition, the emission energy in the quantum well varies according to the thickness of the quantum well and this atomic percentage X.

In the case of a ternary or quaternary semiconductor, i.e. with a ternary or quaternary type alloy, corresponding to a semiconductor III-V comprising at least two elements from column 13, or column IIIA, of the periodic table of elements and at least one element from column 15, or column VA, of the periodic table of elements, the expression “atomic composition of said chemical element” corresponds to the atomic percentage of one of the elements of column 13, for example to the atomic percentage of indium or of aluminium, with respect to the atomic percentage of the other the other of the elements of the column 13, for example to the atomic percentage of gallium.

The light-emitting diode, the device for detecting the value of the wavelength and of the intensity of the light intended to be emitted, the device for controlling and the switched-mode electric power supply may thus form together a feedback loop making it possible to carry out a control and an adjusting of the wavelength and of the intensity of the light emitted by the light-emitting diode of such a light-emitting device.

Such a light-emitting device also makes it possible to offset the effects of the ageing of the light-emitting diode. Indeed, because the wavelength emitted by a light-emitting diode varies over time and its luminosity decreases over time, such a light-emitting device makes it possible to offset these effects due to the ageing of the light-emitting diode and therefore prolong its length of operation and its length of life.

With such light-emitting devices, it is therefore possible to homogenize the emission wavelength of light-emitting diodes that have for example structural variations due to the steps in their manufacture, without having to sort and eliminate a large portion of the chips at the production output. This makes it possible to reduce “binning”, i.e. the sorting of chips after epitaxy and hybridisation due to their dispersion in emission wavelength.

The wavelength emitted by the light-emitting diode corresponds to the wavelength for which the light intensity is maximum in the emissions spectrum of the light-emitting diode.

Such a light-emitting device may correspond for example to a bulb with a light-emitting diode or diodes in which the device for detecting the value of the wavelength and of the intensity of the light intended to be emitted, the device for controlling and the switched-mode electric power supply are made in the form of electronics integrated into the bulb. This light-emitting device may also correspond to a screen, a projector or a display wall comprising several light-emitting diodes.

The gap, or the energy of the band gap, of an emitting layer able to form a quantum well, may be less than the gap of barrier layers between which the emitting layer is arranged.

The light-emitting diode may comprise several emitting layers each able to form a quantum well, with each one of the emitting layers able to include at least one ternary or quaternary semiconductor comprising at least one chemical element from column 13 of the periodic table of elements among Al, Ga and In of which the atomic composition varies along the thickness of said emitting layer, and/or of which the atomic compositions in the emitting layers are different with respect to one another.

A difference between atomic compositions of said chemical element in two emitting layers may be greater than or equal to about 0.2%.

The emitting layer or each one of the emitting layers may be arranged against and between two barrier layers each comprising a semiconductor. The semiconductors of the barrier layers may advantageously be of the same family as that of the emitting layer or as those of the emitting layers.

The barrier layers may each comprise a ternary or quaternary semiconductor comprising at least one chemical element from column 13 of the periodic table of elements among Al, Ga and In of which the atomic composition is of a value less than that of the atomic composition of said chemical element in the emitting layer arranged against and between said barrier layers such that a gap in said emitting layer is less than a gap in said barrier layers, with the chemical elements of the semiconductor of the barrier layers being of a nature similar to the chemical elements of the semiconductor of the emitting layer or layers. Such barrier layers make it possible to widen the range of values over which the wavelength intended to be emitted by the light-emitting diode can be adjusted.

The light-emitting diode may further comprise at least one n-doped semiconductor layer and at least one p-doped semiconductor layer between which are located at least the emitting layer or layers. These doped semiconductor layers form the p-n junction of the light-emitting diode, with the active zone of the light-emitting diode comprising in particular the emitting layer or layers being arranged between these doped semiconductor layers.

The semiconductors used to make the light-emitting diode may all be of the family of nitrides, i.e. comprising nitrogen as a common element of column 15, or column VA, of the periodic table of elements.

When the atomic composition of said chemical element varies along the thickness of the or of each of the emitting layers, the value of this atomic composition may be, at a first face of said emitting layer of each one of said emitting layers arranged on the side of the n-doped semiconductor layer, greater than the value of that at a second face, opposite the first face and arranged on the side of the p-doped semiconductor layer, of said emitting layer or of each one of said emitting layers, and/or, when the atomic compositions of said chemical element in the emitting layers are different with respect to one another, the values of said atomic compositions may increase from one emitting layer to the other in the direction from the p-doped semiconductor layer to the n-doped semiconductor layer.

The light-emitting device may be such that:
a variation in the atomic composition of said chemical element along the thickness of the or of each one of the emitting layers and/or a maximum difference between the atomic compositions of said chemical element in the emitting layers may be between about 0.2% and 2% (value of the variation of the atomic percentage of said chemical element), and/or
the atomic composition of said chemical element along the thickness of the or of each one of the emitting layers and/or the atomic compositions of said chemical element in the emitting layers may be between about 15% and 17% (values of the atomic percentages of said chemical element).

The semiconductor of the emitting layer or the semiconductors of the emitting layers may be InGaN.

The device for detecting the value of the wavelength and of the intensity of the light intended to be emitted by the light-emitting diode may comprise several photodiodes optically coupled to the light-emitting diode and electrically connected to the device for controlling the switched-mode electric power supply. Such photodiodes may in particular be made with the light-emitting diode in the same semiconductor substrate. It is possible to have for example two photodiodes that detect different ranges of wavelengths emitted by the light-emitting diode, the photo-currents outputted by these two photodiodes make it possible to determine the total light power emitted by the light-emitting diode as well as the emissions spectrum of the light-emitting diode and therefore the emission wavelength of the light-emitting diode.

The light-emitting diode may further comprise, at an output face of the light, phosphorus able to modify the wavelength of a portion of the light intended to be emitted by the light-emitting diode.

The periodic signal may be a square signal. This square signal may also be named a rectangular signal, as the value of its duty cycle α is able to vary and is not necessarily equal to 0.5.

The frequency of the periodic signal may be between about 20 Hz and 1 MHz. In this way, the light emitted by the light-emitting device and observed by a person is perceives as being constant by this person due to retinal persistence.

The invention also relates to a device for adjusting a wavelength and an intensity of a light intended to be emitted by a light-emitting diode comprising at least one emitting layer able to form a quantum well and comprising at least one ternary or quaternary semiconductor comprising at least one chemical element from column 13 of the periodic table of elements among Al, Ga and In of which the atomic composition varies along the thickness of the emitting layer, and/or at least two emitting layers able to form two quantum wells and each comprising at least one ternary or quaternary semiconductor comprising at least one chemical element from column 13 of the periodic table of elements among Al, Ga and In, the atomic compositions of said chemical element in the emitting layers being different from one to another, with the device for adjusting comprising at least:
a device for detecting the value of the wavelength and of the intensity of a light intended to be emitted by the light-emitting diode,
a switched-mode electric power supply able to electrically power the light-emitting diode with a periodic signal comprising a duty cycle α such that αε]0;1],
a device for controlling the switched-mode electric power supply, which can alter a peak value and the duty cycle α of the periodic signal respectively according to values of the wavelength and of the intensity of the light intended to be detected and according to the target values of the wavelength and of the intensity.

Such a device for adjusting can for example be used to test light-emitting diodes in order to determine, for each one of these light-emitting diodes, the values of the duty cycle and of the peak value of the electric power signal making it possible to obtain an emission of light for which the wavelength and the intensity correspond to the target values sought.

The invention also relates to a method for adjusting a wavelength and an intensity of a light intended to be emitted by a light-emitting diode comprising at least one emitting layer able to form a quantum well and comprising at least one ternary or quaternary semiconductor comprising at least one chemical element from column 13 of the periodic table of elements among Al, Ga and In of which the atomic composition varies along the thickness of the emitting layer, and/or at least two emitting layers able to form two quantum wells and each comprising at least one ternary or quaternary semiconductor comprising at least one chemical element from column 13 of the periodic table of elements among Al, Ga and In, the atomic compositions of said chemical element in the emitting layers being different from one to another, with the method comprising at least the following steps:
detecting the value of the wavelength and of the intensity of a light emitted by the light-emitting diode,
adjusting a peak value and a duty cycle α such as αε]0;1] of a periodic signal electrically powering the light-emitting diode, respectively according to the values of the wavelength and of the intensity of the light detected and according to the target values of the wavelength and of the intensity,

with these steps being repeated iteratively until the values of the wavelength and of the intensity of the light detected are substantially equal to the target values of the wavelength and of the intensity.

### BRIEF DESCRIPTION OF THE DRAWINGS

This invention shall be better understood when reading the description of embodiments provided solely for the purposes of information and in no way limiting in reference to the annexed drawings wherein:

FIG. 1 diagrammatically shows a light-emitting device, subject-matter of this invention, according to a particular embodiment;

FIG. 2 diagrammatically shows an electrical signal electrically powering an LED of the light-emitting device, subject-matter of this invention;

FIG. 3 diagrammatically shows a first embodiment of an LED of the light-emitting device, subject-matter of this invention;

FIG. 4 shows the energy of the band gap within the active zone of the LED according to the first embodiment, according to the position along the thickness of the active zone of the LED;

FIG. 5 shows the rate of radiative recombinations within the emitting layer of the LED according to the first embodiment, according to the position along the thickness of the emitting layer of the LED and for a current density of about 100 A/cm² passing through the LED;

FIG. 6 shows the light intensity of the LED according to the first embodiment according to the emission energy when the LED is passed through by a current density of about 100 A/cm²;

FIG. 7 shows the rate of radiative recombinations within the emitting layer of the LED according to the first embodiment, according to the position along the thickness of the emitting layer of the LED and for a current density of about 450 A/cm² passing through the LED;

FIG. 8 shows the light intensity of the LED according to the first embodiment according to the emission energy when the LED is passed through by a current density of about 450 A/cm²;

FIG. 9 diagrammatically shows a second embodiment of an LED of the light-emitting device, subject-matter of this invention;

FIGS. 10 to 12 show band structures of the active zone of the LED, according to different embodiments, of the light-emitting device, subject-matter of this invention;

FIGS. 13A and 13B diagrammatically show embodiments of an LED, in the form of nanowire, of the light-emitting device, subject-matter of this invention.

Identical, similar or equivalent parts of the various figures described hereinafter bear the same numerical references in such a way as to facilitate passing from one figure to another.

The various parts shown in the figures are not necessarily shown according to a uniform scale, in order to make the figures more legible.

The various possibilities (alternatives and embodiments) must be understood as not being exclusive with respect to one another and can be combined together.

### DETAILED DISCLOSURE OF PARTICULAR EMBODIMENTS

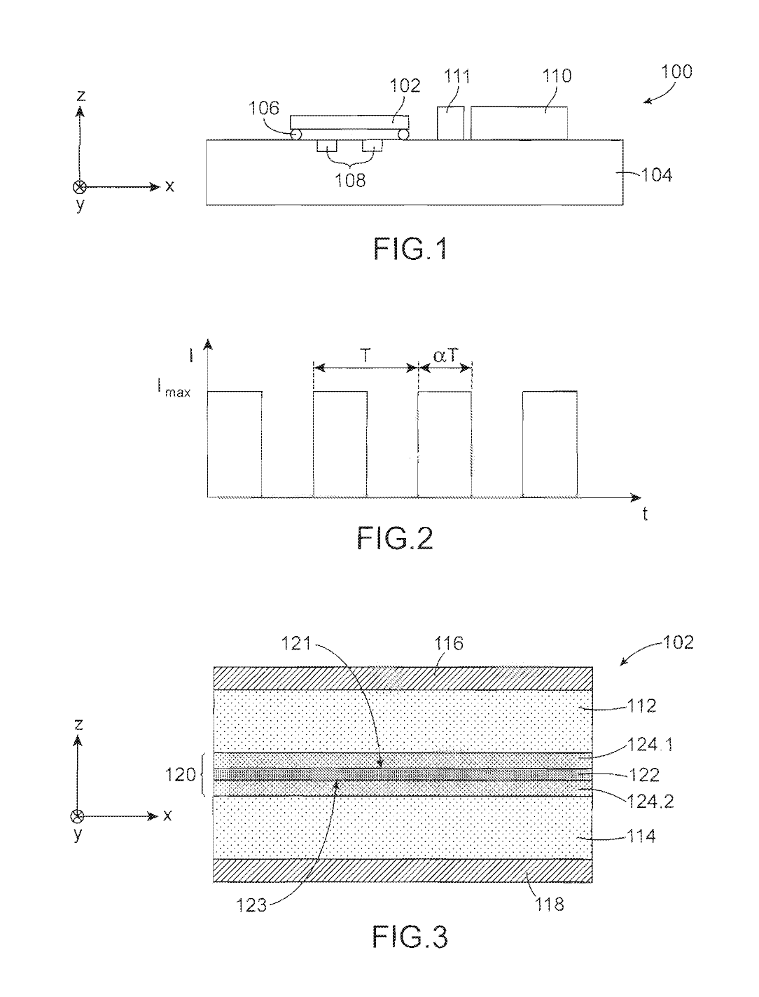

Reference is first made to FIG. 1 which diagrammatically shows a light-emitting device 100 according to a particular embodiment.

The light-emitting device 100 comprises an LED 102 which here is intended to carry out a light emission of white colour. This light emission of white colour is obtained thanks to an emitting structure of the LED 102 able to emit a blue light and to phosphorus covering this emitting structure, with this phosphorus making it possible to convert a portion of the blue light emitted into a light of yellow colour. The LED 102 is mechanically and electrically coupled on a substrate 104, for example made of silicon, via beads of fusible material 106. Alternatively, the LED 102 could be made directly by growth on the substrate 104. The LED 102 is able to emit both from a rear face located facing the substrate 104 and from a front face opposite the rear face.

The light-emitting device 100 comprises a device for detecting the value of a wavelength and of an intensity of the light emitted by the LED 102 comprising here two photodiodes 108 made in the substrate 104, and which are arranged facing the rear face of the LED 102. A first of the two photodiodes 108 detects the wavelengths less than a first cutoff wavelength named λ₁ and for example equal to about 450 nm. A second of the two photodiodes 108 detects the wavelengths greater than a second cutoff wavelength named λ₂ which is such that λ₂>λ₁ and for example equal to about 470 nm. The first cutoff wavelength λ₁ is for example defined by a low-pass filter formed in front of the first of the two photodiodes 108 (between this first photodiode and the LED 102) and the second cutoff wavelength λ₂ is for example defined by a high-pass filter formed in front of the second of the two photodiodes 108 (between this second photodiode and the LED 102).

The device for detecting the value of a wavelength and of the intensity of the light emitted by the LED 102 also comprises means for calculating (not shown in FIG. 1) coupled to the photodiodes 108 and making it possible to calculate, using the sum of the electrical signals, or photo-currents, outputted by the photodiodes 108 the intensity of the light, or total light power, emitted by the LED 102. These means for calculating also make it possible to calculate the wavelength of the light emitted by the LED 102 using the relationship between the electrical signals outputted by the two photodiodes 108.

Alternatively, the detecting of the value of the wavelength emitted by the LED 102 and the detecting of the intensity of the light emitted by the LED 102 could be carried out by two separate devices.

The light-emitting device 100 also comprises a switched-mode electric power supply 110 making it possible to electrically power the LED 102. This switched-mode power supply 110 outputs a voltage or a current in the form of a periodic signal, for example a square signal, with a period T and for which a peak value Imax or Umax and a duty cycle α can be adjusted, the duty cycle α being such that αε]0;1]. FIG. 2 shows an example of the periodic signal of the electrical supply of the LED 102, here a current in the form of a square signal.

These parameters of the electrical signal outputted by the switched-mode power supply 110 are controlled by a control device 111 receiving as input the detected values of the wavelength and of the intensity of the light emitted by the LED 102 and outputting a control signal sent to the switched-mode power supply 110 (alternatively, it is possible that the control device 111 and the switched-mode electric power supply 110 form a single element). These elements form a feedback loop such that the peak value Imax or Umax and the duty cycle α of the signal outputted by the switched-mode power supply 110 depend on the wavelength and the intensity desired for the light intended to be emitted by the LED 102. As such, in order to adjust the intensity and the wavelength of the light emitted by the LED 102, the peak value and the duty cycle of the power signal are adjusted so that the sum and the relationship of the photo-currents outputted by the photodiodes 108 are values equal to those obtained for a desired intensity and wavelength (these target values of the sum and of the relationship of the photo-currents are known or are determined beforehand with an LED serving as a reference). When the detecting of the wavelength and the detecting of the light intensity are carried out by two separate devices, these two devices can be coupled optically to the LED 102 and electrically connected to the control device 111 by forming two feedback loops.

The device for detecting the light-emitting device 100 can be made in an integral manner with the substrate as described for example in document US 2009/0040755 A1.

A first embodiment of the LED 102 is diagrammatically shown in FIG. 3.

The LED 102 comprises a p-n junction formed by an n-doped semiconductor layer 112 and a p-doped semiconductor layer 114.

The semiconductor of the layers 112 and 114 is for example GaN. The layer 112 is n-doped with a concentration of donors between about 10¹⁷ and 5·10¹⁹ donors/cm³. The layer 114 is p-doped with a concentration of acceptors between about 10¹⁷ and 5·10¹⁹ donors/cm³.

These two layers 112 and 114 each have for example a thickness (dimension according to the Z-axis shown in FIG. 3) between about 20 nm and 10 μm. A first transparent electrode 116 is arranged against the n-doped layer 112 and forms a cathode of the LED 102, and a second transparent electrode 118 is arranged against the p-doped layer 114 and forms an anode of the LED 102.

The LED 102 comprises, between the n-doped layer 112 and the p-doped layer 114, an active zone 120 comprising an emitting layer 122 comprising a ternary or quaternary semiconductor comprising at least one chemical element from column 13 of the periodic table of elements among Al, Ga and In, here InGaN, forming a quantum well of the LED 102. This semiconductor can further comprise at least one chemical element from column 15 of the periodic table of elements, able to be chosen among N, P, As and Sb. The thickness of the emitting layer 122 is for example equal to about 3 nm and more generally between about 0.5 nm and 10 nm. The active zone 120 also comprises two barrier layers 124.1 and 124.2 comprising preferably the same semiconductor as the base semiconductor to which said chemical element, for example indium, is added in order to form the ternary or quaternary semiconductor of the emitting layer 122, i.e. here GaN, between which the emitting layer 122 is arranged. As such, the first barrier layer 124.1 is arranged between the n-doped layer 112 and the emitting layer 122, and the second barrier layer 124.2 is arranged between the p-doped layer 114 and the emitting layer 122. The thickness of each one of the barrier layers 124.1 and 124.2 is for example between about 1 nm and 25 nm. All of the layers of the active zone 120 of the LED 102, i.e. the emitting layer 122 and the barrier layers 124.1 and 124.2, comprise unintentionally doped materials (of a concentration in residual donors n_{nid} equal to about 10¹⁷ donors/cm³, or between about 10¹⁵ and 10¹⁸ m donors/c³).

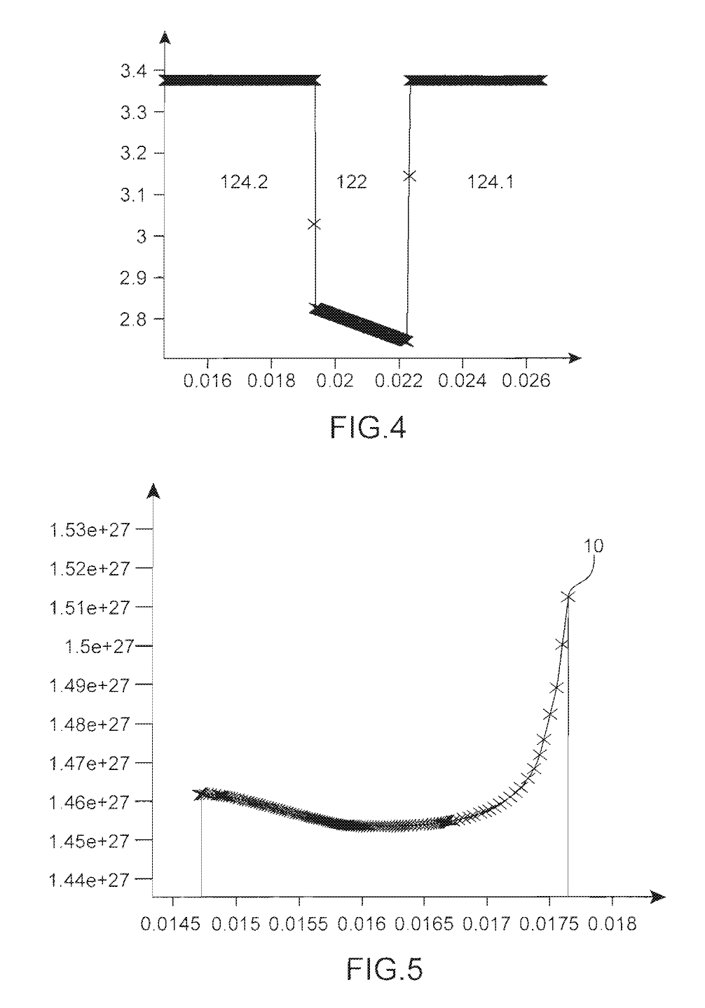

The atomic composition of said chemical element of the semiconductor of the emitting layer 122, corresponding here to the atomic composition of indium in the InGaN of the emitting layer 122, or to the atomic percentage of indium in the InGaN, varies along the thickness (dimension according to the Z-axis shown in FIG. 3) of the emitting layer 122. In this embodiment, this indium composition varies in a decreasing manner in the direction from the n-doped layer 112 to the p-doped layer 114. More precisely, indium composition of the emitting layer 122 at a first face 121 located against the first barrier layer 124.1, i.e. on the side of the n-doped layer 112, is equal to about 16% (value of the atomic percentage of indium), with this indium composition varying in a substantially continuous and decreasing manner along the thickness of the emitting layer 122 until reaching, at a second face 123 of the emitting layer 122 located against the second barrier layer 124.2, i.e. on the side of the p-doped layer 114, a value equal to about 15%. The energy of the band gap obtained within such an emitting layer 122, as well as in a portion of the barrier layers 124.1 and 124.2 in contact with the emitting layer 122, according to the thickness of these layers, is shown in FIG. 4.

Thanks to this variation in the indium composition in the semiconductor of the emitting layer 122 of the LED 102 and to the elements described hereinabove of the light-emitting device 100, it will be possible to easily adjust the emission wavelength of the LED 102 as well as the light emission intensity of the LED 102 to desired target values.

FIG. 5 shows the rate of radiative recombinations within the emitting layer 122, according to the position along the thickness of the emitting layer 122, for a current density of about 100 A/cm² passing through the LED 102 (with this value of current density of about 100 A/cm² corresponding to a standard value for powering an LED). It can be seen in this FIG. 5 that a maximum value, referenced as 10, of the rate of radiative recombinations within the emitting layer 122 is obtained on the side that is the richest in indium, i.e. at the first face 121 of the emitting layer 122 located against the first barrier layer 124.1 and which comprises an indium composition equal to about 16%, where the energy of the band gap is the weakest in the emitting layer 122, on the side of the n-doped layer 112.

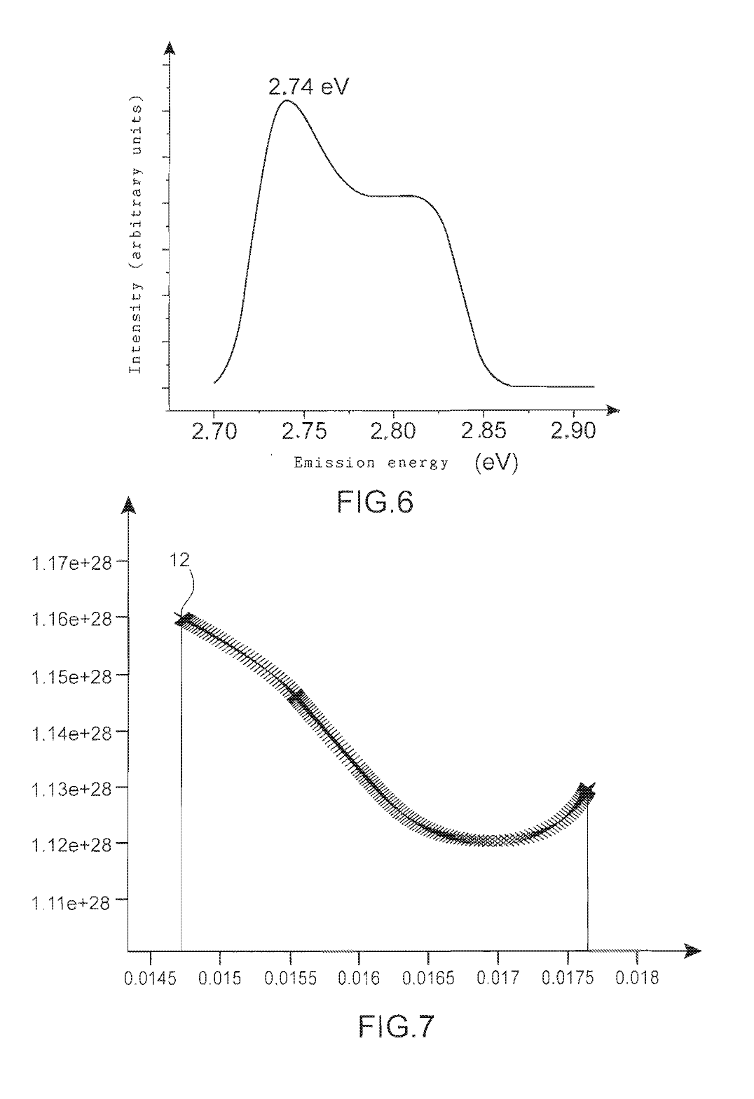

FIG. 6 shows the light intensity (in arbitrary units in this figure) of the LED 102 according to the emission energy (in eV) when the LED 102 is passed through by a current density of about 100 A/cm². It can be seen in this FIG. 6 that the emission intensity is maximum for an emission energy of about 2.74 eV, which corresponds to a wavelength equal to about 452 nm. This value of 452 nm is therefore assimilated to the wavelength emitted by the LED 102 when the latter is powered with a current density equal to about 100 A/cm².

FIG. 7 shows the rate of radiative recombinations within the emitting layer 122, according to the position along the thickness of the emitting layer 122, for a current density of about 450 A/cm² passing through the LED 102. It can be seen in this FIG. 7 that a maximum value, referenced as 12, of the rate of radiative recombinations within the emitting layer 122 is obtained on the side that is the less rich in indium, i.e. at the second face 123 of the emitting layer 122 located against the second barrier layer 124.2 and which comprises an indium composition equal to about 15%, where the energy of the band gap is the strongest in the emitting layer 122, on the side of the p-doped layer 114.

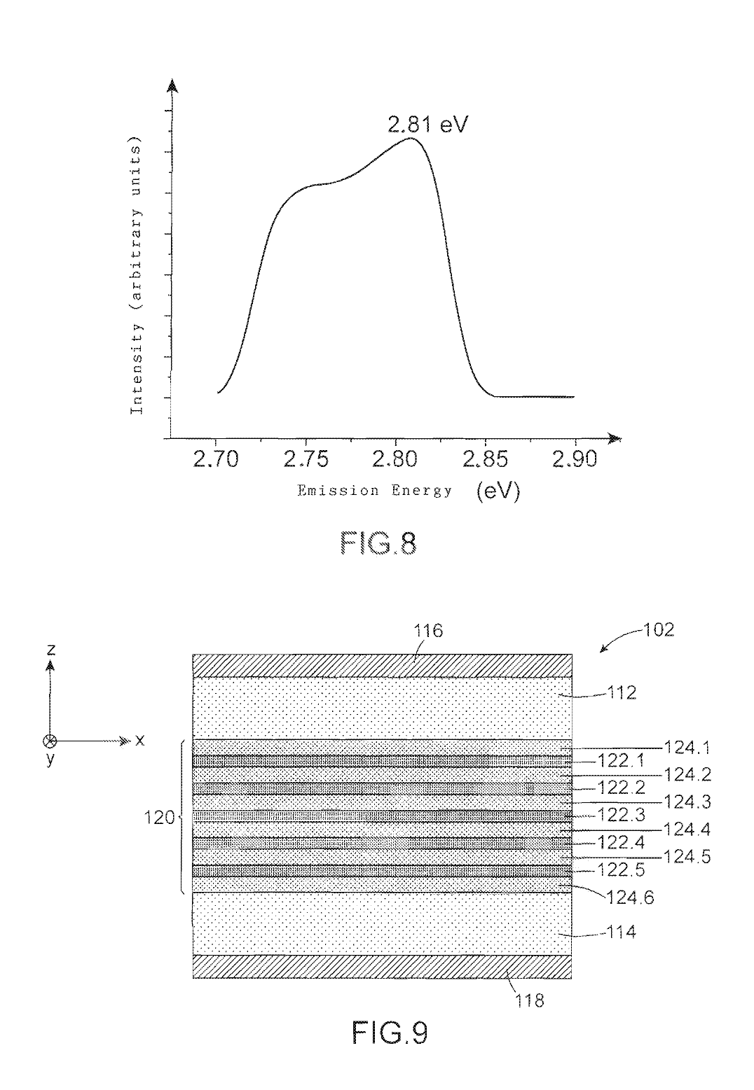

FIG. 8 shows the light intensity (in arbitrary units) of the LED 102 according to the emission energy (in eV) when the LED 102 is passed through by a current density of about 450 A/cm². It can be seen in this FIG. 8 that the emission intensity is maximum for an emission energy of about 2.81 eV, which corresponds to a wavelength equal to about 441 nm. This value of 441 nm is therefore assimilated to the wavelength emitted by the LED 102 when the latter is powered with a current density equal to about 450 A/cm².

In FIGS. 5 to 8, it can be seen that the variation of the indium composition within the emitting layer 122 makes it possible to have a strong adaptability of the wavelength emitted by the emitting layer 122 by varying the current density injected into the LED 102. Indeed, by varying this current density, the “position” within the quantum well is varied whereon the maximum radiative recombinations is produced. However, due to the fact that the indium composition varies according to the position within this quantum well, the emission energy obtained, and therefore the wavelength emitted by the LED 102, then varies also according to this current density.

In the example described hereinabove, the emission wavelength of the LED 102 varies by about 9 nm by varying the current density by a factor equal to about 4.5. More generally, with a variation of about 1% in the indium composition within the emitting layer of the LED, it is possible to adjust the emission wavelength over a range of about 10 nm by varying the current density by a factor equal to about 5.

Thanks to the device for detecting the value of the wavelength emitted by the LED 102 which is formed by the two photodiodes 108 of the light-emitting device 100 described hereinabove, with this device for detecting being connected to the control device 111 which itself is connected to the switched-mode power supply 110 by forming a feedback loop, the wavelength emitted by the LED 102 is therefore adjusted (within the range of adjustment obtained by the variation of the indium composition of the emitting layer 122) via the adjusting of the peak value of the electric power signal of the LED 102, for example here the adjusting of the value Imax of the current outputted by the switched-mode power supply 110 (with the current density passing through the LED 102 depending on this value Imax), which is carried out according to the desired emission wavelength. As such, if the photodiodes 108 detect that the LED 102 is emitting a wavelength with a value that is too high, the control device 111 receiving as input the signals outputted by the photodiodes 108 then orders the switching electric power supply 110 to output a current with a stronger amplitude. Inversely, if the photodiodes 108 detect that the LED 102 is emitting a light with a wavelength that is too low, the control device 111 then orders the switched-mode electric power supply 110 to output a current with a lower amplitude.

The modification of the peak value of the electric power signal of the LED 102, and therefore of the current density passing through the LED 102, affects the wavelength emitted by the LED 102 but also the intensity of the light emitted by the LED 102. In order to prevent the light intensity emitted by the LED 102 from being affected by the modification in the current density passing through the LED 102 carried out to adjust the emitted wavelength (with the light intensity sought corresponding for example to that obtained when the LED 102 is passed through by a current density of about 100 A/cm²), this light emission intensity of the LED 102 is adjusted to the desired level via the adjustment of the duty cycle α of the periodic electric power signal of the LED 102.

Indeed, by powering the LED 102 with a voltage or a current in the form of a periodic square signal comprising a duty cycle α (which is equal to the ratio of the duration during which, during a period T, the current is equal to the peak value, over the total duration of the period T), the intensity of the light emitted by the LED 102 will depend on the peak value but also on the value of a. As such, in the example described hereinabove, considering that the light intensity sought corresponds to that obtained when the LED 102 is passed through by a current density equal to about 100 A/cm², the value of a is for example chosen equal to about 0.22 when the LED 102 is passed through by a current density equal to about 450 A/cm² in order to obtain a light of the same light intensity as when the LED 102 is passed through by a current density equal to about 100 A/cm².

The period T of the periodic electric power signal of the LED 102 is chosen sufficiently small so as not to observe any flickering or blinking of the LED 102, and that corresponds for example to a frequency between about 20 Hz and 1 MHz.

As such, if the device for detecting the intensity of the light emitted by the LED 102 detects an intensity that is too strong, the control device 111 receiving as input the signal outputted by this device for detecting then orders the switched-mode electric power supply 110 to output the output current with a smaller duty cycle α. Inversely, if the device for detecting the intensity of the light emitted by the LED 102 detects that the LED 102 is emitting a light with an intensity that is too low, the control device 111 then orders the switched-mode electric power supply 110 to output the output current with a larger duty cycle α.

FIG. 9 diagrammatically shows a second embodiment of the LED 102. With regards to the LED 102 described hereinabove in liaison with FIG. 3, the active zone 120 of the LED 102 according to this second embodiment comprises several quantum wells formed by an alternating of emitting layers 122.1 to 122.5 and of barrier layers 124.1 to 124.6, with each one of the emitting layers 122.1 to 122.5 being arranged between and against two of the barrier layers 124.1 to 124.6. Each one of the emitting layers 122.1 to 122.5 comprises InGaN of which the indium composition varies along the thickness of these layers such that this composition varies in an increasing manner in the direction from the p-doped layer 114 to the n-doped layer 112, as for the emitting layer 122 described hereinabove for the LED 102 according to the first embodiment. In the embodiment of FIG. 9, the emitting layers 122.1 to 122.5 are similar with respect to one another, and each has an indium composition varying from 15% to 16% from one face to the other of each one of these layers in the direction from the p-doped layer 114 to the n-doped layer 112. Each one of the emitting layers 122.1 to 122.5 has for example a thickness (dimension according to the Z-axis shown in FIG. 9) equal to about 1 nm, and each one of the barrier layers 124.1 to 124.6 has for example a thickness equal to about 5 nm.

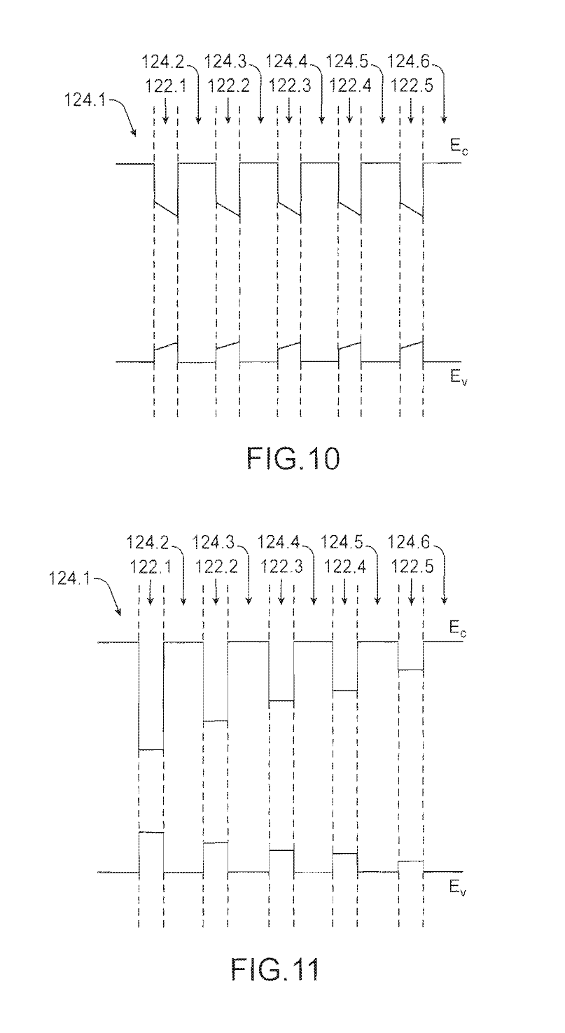

The band structure at 0 V of the active zone 120 of the LED 102 according to the second embodiment is diagrammatically shown in FIG. 10 (whereon the X-axis represents the direction of growth of the layers of the LED 102, and the Y-axis represents the energy of the bands within the layers of the LED 102). The references of the various layers of the active zone 120 are included in this figure. It can be seen in FIG. 10 that the variation in the indium composition in each one of the emitting layers 122.1 to 122.5 generates variations in the valency and conduction bands within the quantum wells of the active zone 120 formed by these emitting layers 122.1 to 122.5.

As for the LED 102 according to the first embodiment, it is therefore possible to adjust the wavelength emitted by each quantum well by adjusting the current density passing through the LED 102. Due to the fact that the indium composition in each one of the emitting layers 122.1 to 122.5 varies identically from one layer to another, the wavelength emitted from each one of the quantum wells formed by these layers is substantially identical from one quantum well to the other.

According to an alternative of the second embodiment of the LED 102 shown in FIG. 9, it is possible for each emitting layer 122.1 to 122.5 to comprise InGaN for which the indium composition is constant within each one of the emitting layers 122.1 to 122.5, but which is different from one emitting layer to the other. As such, by varying the current density passing through the LED 102, the filling of the quantum wells of the LED 102 by the charge carriers is modified. The quantum well, among those of the active zone 120, that carries out the light emission of such an LED 102 thus changes according to the value of the current density passing through the LED 102. Due to the fact that quantum wells have different indium compositions, this therefore implies a variation in the wavelength emitted by the LED 102. The difference in indium composition between the last emitting layer 122.5, which corresponds to that of which the InGaN comprises the lowest indium composition, and the first emitting layer 122.1, which corresponds to that of which the InGaN comprises the strongest indium composition, i.e. the maximum difference between the atomic indium compositions in the emitting layers 122.1 to 122.5, can be of the same order of magnitude as the difference in indium composition within a single emitting layer of the LED 102 according to the second embodiment described in relation with FIG. 10, when the indium composition varies within each one of the emitting layers. The indium composition of the InGaN of the first emitting layer 122.1 is for example equal to about 16%, and that of the last emitting layer 122.5 is for example equal to about 15%. FIG. 11 shows band structure at 0 V of such an LED 102 according to this alternative of the second embodiment (whereon the X-axis represents the direction of growth of the layers of the LED 102, and the Y-axis represents the energy of the bands within the layers of the LED 102).

According to another alternative, it is possible to make a combination of the embodiments described hereinabove in liaison with FIGS. 10 and 11, i.e. to have both a variation in the atomic composition of said chemical element from column 13 of the periodic table of elements (for example indium) within each one of the emitting layers of the LED, and that these variations are different from one emitting layer to the other. It is for example possible to have a variation of about 1% of the composition in indium along the thickness of each one of the emitting layers, and to have indium compositions of which the maximum and minimum values vary between 0.1% and 0.5% from one emitting layer to another.

According to the third embodiment, the LED 102 can comprise two emitting layers, forming two quantum wells, each comprising a ternary or quaternary semiconductor comprising at least one chemical element from column 13 of the periodic table of elements among Al, Ga and In, with the atomic compositions of said chemical element in these two emitting layers being different by at least 0.2%. This semiconductor can further comprise at least one chemical element from column 15 of the periodic table of elements, able to be chosen among N, P, As and Sb. These two emitting layers comprise for example InGaN comprising respectively atomic indium compositions equal to about 16% and 16.2%. These two emitting layers are for example separated from one another by a barrier layer of GaN with a thickness equal to about 3 nm.

In all of the embodiments and alternatives for making the light-emitting diode described beforehand, the variation in the atomic composition of said chemical element from column 13 of the periodic table of elements, for example the atomic composition of indium, along the thickness of the or of each one of the emitting layers, or a maximum difference between the atomic compositions of said chemical element in the emitting layers, can in particular be between about 0.1% and 2%, or between about 0.2% and 2%, or between about 0.2% and 1%. In addition, this atomic composition of said chemical element along the thickness of the or of each one of the emitting layers or the atomic compositions of said chemical element in the emitting layers can be between about 15% and 17%, or between about 15% and 16%, or between about 16% and 17%.

Alternatively, the LED 102 can comprise a different number of emitting layers each forming a light emission quantum well, advantageously greater than 5 and for example equal to 10. When the LED 102 comprises 10 emitting layers, the first emitting layer (the one located on the side of the n-doped layer 112) can comprise InGaN with an indium concentration equal to about 17% and the last emitting layer (the one located on the side of the p-doped layer p 114) can comprise InGaN with an indium concentration equal to about 15%. With such an LED 102, it is possible to vary the wavelength emitted over a range of about 15 nm, for example between about 455 nm and 440 nm for current densities varying between 10 A/cm² and 100 A/cm².

As an alternative of all of the embodiments and alternatives for making the light-emitting diode, it is possible that the barrier layers comprise at least one ternary or quaternary semiconductor, for example InGaN, comprising at least one chemical element from column 13 of the periodic table of elements, e.g. chosen among Al, Ga and In (indium for example), of which the atomic composition is of a value less than that of the atomic composition of said chemical element in the emitting layer arranged against and between said barrier layers. In addition, the n-doped layer 112 can also comprise a semiconductor similar to that of the emitting layers such as InGaN.

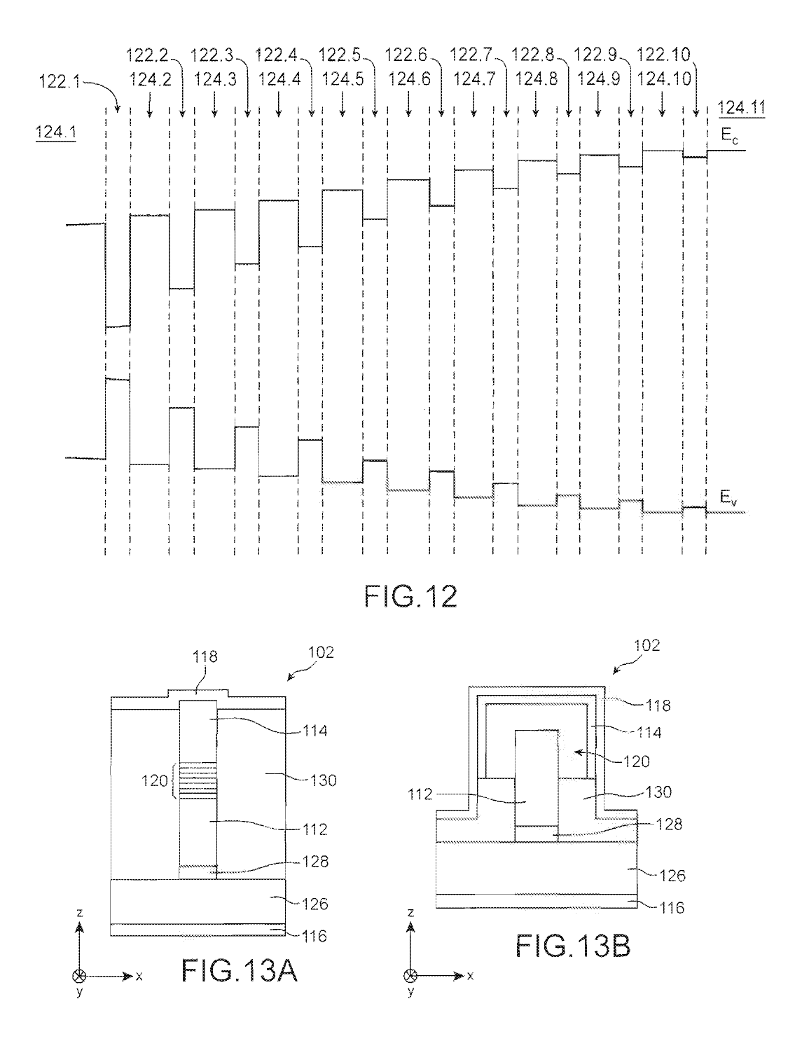

FIG. 12 shows the band structure at 0 V of such an LED 102 comprising 10 emitting layers 122.1 to 122.10 made of InGaN comprising different atomic indium compositions ranging from about 17% on the side of the n-doped layer 112 to about 15% on the side of the p-doped layer 114. The n-doped layer 112 can comprise InGaN with an atomic indium composition equal to about 12%, and the p-doped layer 114 can comprise GaN. The barrier levels 124.1 to 124.11 made of InGaN also comprise indium of which the atomic composition varies in an increasing manner in the direction from the p-doped layer 114 to the n-doped layer 112. In such a configuration, for variations in the current density passing through the LED 102 ranging from about 50 A/cm² to 200 A/cm², it is possible to vary the wavelength over a range of about 20 nm, for example between about 460 nm and 440 nm.

In the various embodiments described hereinabove, the semiconductor used for the various elements of the LED 102 comprises GaN (with the adding of indium in order to make emitting layers, and possibly for the making of barrier layers and/or of the n-doped layer 112). However, it is possible to make the LED 102 using any semiconductor that makes it possible to make p-n junctions adapted for light-emitting diodes with one or several quantum wells comprising a ternary or quaternary semiconductor comprising at least one chemical element from column 13 of the periodic table of elements among Al, Ga and In. It is in particular possible to use, instead of GaN, semiconductors with large gaps such as for example GaInN, ZnO, or ZnMgO that can potentially be used to carry out a light emission in the range of wavelengths corresponding to the colour blue or to ultra-violet, with the chemical element from column 13 of the periodic table of elements added in order to make the emitting layers and possibly for the making of barrier layers and/or the n-doped layer able to be indium or aluminium or gallium. It is also possible to use semiconductors with smaller gaps such as for example InP, GaP, InGaP, InAs, GaAs, InGaAs, AlGaInP, AlGaAs.

The LED 102 described hereinabove according to the various embodiments can be made in the form of a planar diode, i.e. in the form of a stack of layers formed for example by epitaxial growth on a substrate, with the main faces of the various layers being arranged in parallel to the plane of the substrate (parallel to the plane (X,Y)).

Alternatively, the LED 102 can also be made in the form of a nanowire. FIG. 13A shows such an LED 102 made in the form of an axial nanowire, with this nanowire comprising a stack formed of the first electrode 116, of a substrate 126 of n-type semiconductor (for example silicon), of a nucleation layer 128 allowing for the growth of the nanowire, of the first layer 112 of n-doped semiconductor, of the active zone 120, of the second layer 114 of p-doped semiconductor, and of the second electrode 118. An insulating material 130 can surround at least a portion of this nanowire which extends parallel to the Z-axis.

FIG. 13B shows an LED 102 made in the form of a radial nanowire, with this nanowire comprising a stack formed of the first electrode 116, of the substrate 126 of semiconductor, of the nucleation layer 128 and of the first layer 112 of n-doped semiconductor. Insulating portions 130 partially surround the first layer 112 and the nucleation layer 128. The active zone 120, comprising the barrier layers 124 and the emitting layers 122, is made such that it surrounds a portion of the n-doped layer 112. The second layer 114 of p-doped semiconductor is made such that it surrounds the active zone 120. Finally, the second electrode 118 is made by covering the second layer 114.

As an alternative to the two embodiments described in the FIGS. 13A and 13B, the structure of these nanowires can be inverted, with in this case a substrate 128 of a semiconductor of the p-doped type whereon are made the second 114 then the other elements of the LED 102 in the opposite order of that described in the FIGS. 13A and 13B.

The various characteristics (thicknesses, doping, etc.) disclosed hereinabove for the LED 102 of the planar type can be similar for the LED 102 made in the form of a nanowire.

According to another embodiment, the device 100 described hereinabove may not be intended to carry out a light emission, and correspond to a device for adjusting the wavelength and an intensity of a light intended to be emitted by an LED. Such a device for adjusting can for example be used to test light-emitting diodes in order to determine, for each one of these light-emitting diodes, the values of the duty cycle and of the peak value of the electric power signal making it possible to obtain an emission of light for which the wavelength and the intensity correspond to the target values sought. In this case, the device 100 can comprise a location (not shown) that makes it possible to temporarily connect the tested LEDs.

1.-14. (canceled)

15. A light-emitting device comprising at least:
a light-emitting diode comprising at least one emitting layer able to form a quantum well and comprising a ternary or quaternary semiconductor including at least one chemical element from column 13 of the periodic table of elements among Al, Ga and in of which the atomic composition varies over the thickness of said at least one emitting layer,
a detector of the value of a wavelength and of an intensity of a light intended to be emitted by the light-emitting diode,
a switched-mode electric power supply able to electrically power the light-emitting diode with a periodic signal comprising a duty cycle α such that αε]0;1],
a controller of the switched-mode electric power supply which can alter a peak value and the duty cycle α of the periodic signal respectively according to values of the wavelength and of the intensity of the light intended to be detected and according to the target values of the wavelength and of the intensity.

16. The light-emitting device according to claim 15, wherein the light-emitting diode comprises several emitting layers each able to form a quantum well, wherein each one of said emitting layers includes a ternary or quaternary semiconductor comprising at least one chemical element from column 13 of the periodic table of elements among Al, Ga and In of which the atomic composition varies along the thickness of said emitting layer.

17. The light-emitting device according to claim 16, in which the atomic compositions of said chemical element in the emitting layers are different with respect to one another.

18. The light-emitting device according to claim 17, wherein a difference between atomic compositions of said chemical element in two emitting layers is greater than or equal to about 0.2%.

19. The light-emitting device according to claim 15, wherein said at least one emitting layer is arranged against and between two barrier layers each comprising a semiconductor.

20. The light-emitting device according to claim 19, in which the barrier layers each comprise a ternary or quaternary semiconductor comprising at least one chemical element from column 13 of the periodic table of elements among Al, Ga and In of which the atomic composition is of a value less than that of the atomic composition of said chemical element in said at least one emitting layer arranged against and between said barrier layers such that a gap in said at least one emitting layer is less than a gap in said barrier layers, with the chemical elements of the semiconductor of the barrier layers being of a nature similar to the chemical elements of the semiconductor of said at least one emitting layer.

21. The light-emitting device according to claim 15, wherein the light-emitting diode further comprises at least one n-doped semiconductor layer and at least one p-doped semiconductor layer between which are located said at least one emitting layer.

22. The light-emitting device according to claim 21, wherein the value of the atomic composition of said chemical element which varies along the thickness of said at least one emitting layer is, at a first face of said at least one emitting layer arranged on the side of the n-doped semiconductor layer, greater than the value of that at a second face, opposite the first face and arranged on the side of the p-doped semiconductor layer, of said at least one emitting layer.

23. The light-emitting device according to claim 17, wherein the light-emitting diode further comprises at least one n-doped semiconductor layer and at least one p-doped semiconductor layer between which are located said at least one emitting layer, and wherein the values of the atomic compositions of said chemical element in the emitting layers increase from one emitting layer to the other in the direction from the p-doped semiconductor layer to the n-doped semiconductor layer.

24. The light-emitting device according to claim 15, wherein a variation in the atomic composition of said chemical element along the thickness of said at least one emitting layer is between about 0.2% and 2%, and/or the atomic composition of said chemical element along the thickness of said at least one emitting layer is between about 15% and 17%.

25. The light-emitting device according to claim 17, wherein a maximum difference between the atomic compositions of said chemical element in the emitting layers is between about 0.2% and 2%, and/or the atomic compositions of said chemical element in the emitting layers are between about 15% and 17%.

26. The light-emitting device according to claim 15, wherein the semiconductor of said at least one emitting layer is InGaN.

27. The light-emitting device according to claim 15, wherein the detector of the value of the wavelength and of the intensity of the light intended to be emitted by the light-emitting diode comprises several photodiodes optically coupled to the light-emitting diode and electrically connected to the controller.

28. The light-emitting device according to claim 15, wherein the light-emitting diode further comprises, at an output face of the light, phosphorus able to modify the wavelength of a portion of the light intended to be emitted by the light-emitting diode.

29. The light-emitting device according to claim 15, wherein the periodic signal is a square signal.

30. A device for adjusting a wavelength and an intensity of a light intended to be emitted by a light-emitting diode comprising at least one emitting layer able to form a quantum well and comprising at least one ternary or quaternary semiconductor comprising at least one chemical element from column 13 of the periodic table of elements among Al, Ga and In of which the atomic composition varies along the thickness of said at least one emitting layer, wherein said device for adjusting comprises at least:
a detector of the value of the wavelength and of the intensity of a light intended to be emitted by the light-emitting diode,
a switched-mode electric power supply able to electrically power the light-emitting diode with a periodic signal comprising a duty cycle α such that αε]0;1],
a controller of the switched-mode electric power supply which can alter a peak value and the duty cycle α of the periodic signal respectively according to values of the wavelength and of the intensity of the light intended to be detected and according to the target values of the wavelength and of the intensity.

31. A method for adjusting a wavelength and an intensity of a light intended to be emitted by a light-emitting diode comprising at least one emitting layer able to form a quantum well and comprising a ternary or quaternary semiconductor comprising at least one chemical element from column 13 of the periodic table of elements among Al, Ga and In of which the atomic composition varies along the thickness of said at least one emitting layer, wherein the method comprises at least the following steps:
detecting the value of the wavelength and of the intensity of a emitted by the light-emitting diode,
adjusting a peak value and a duty cycle α such as αε]0;1], of a periodic signal electrically powering the light-emitting diode, respectively according to the values of the wavelength and of the intensity of the light detected and according to the target values of the wavelength and of the intensity,
wherein these steps are repeated iteratively until the values of the wavelength and of the intensity of the light detected are substantially equal to the target values of the wavelength and of the intensity.
